(19) United States
(12) Patent Application Publication
(10) Pub. No.: US 2024/0379334 A1
(43) Pub. Date: Nov. 14, 2024

(54) COOLANT TUBE BLOCK ASSEMBLY AND SEMICONDUCTOR PROCESSING DEVICE INCLUDING THE SAME

(71) Applicant: SAMSUNG ELECTRONICS CO., LTD., Suwon-si (KR)

(72) Inventors: Woojin Jang, Suwon-si (KR); Wonyoung Jee, Suwon-si (KR); Kyungsun Kim, Suwon-si (KR); Mingil Kim, Suwon-si (KR); Sanghun Bang, Suwon-si (KR); Dongseok Han, Suwon-si (KR); Changkyu Kwag, Suwon-si (KR); Jihwan Kim, Suwon-si (KR); Junghyun Song, Suwon-si (KR); Kuihyun Yoon, Suwon-si (KR)

(21) Appl. No.: 18/651,124

(22) Filed: Apr. 30, 2024

(30) Foreign Application Priority Data
May 11, 2023 (KR) 10-2023-0060893

(51) Int. Cl. H01J 37/32

(52) U.S. Cl. CPC H01J 37/32724; H01J 2237/2001

(57) ABSTRACT

An example coolant tube block assembly includes a first coolant tube block including at least one of a first coolant flow path tube and a second coolant flow path tube; a hub block configured to expose at least one of the first coolant flow path tube and the second coolant flow path tube on one side, and connected to a lower side of the first coolant tube block; a second coolant tube block including at least one third coolant flow path tube and at least one fourth coolant flow path tube communicating with at least one of the first coolant flow path tube and the second coolant flow path tube, and stacked with the first coolant tube block through the hub block; and a clamp disposed at a lower portion of the second coolant tube block and fastened to a fastening groove formed outside the hub block.

### CROSS-REFERENCE TO RELATED APPLICATION

This application claims priority to Korean Patent Application No. 10-2023-0060893, filed on May 11, 2023, in the Korean Intellectual Property Office, the disclosure of which is incorporated herein by reference in its entirety.

### BACKGROUND

During a semiconductor manufacturing process, a wafer processing device including a vacuum chamber is used for deposition, etching, and annealing processes. In the semiconductor processing device, an exhaust passage is formed between an exhaust port and a reaction region to which a process gas is supplied. The process gas moves from the reaction region to the exhaust passage by exhaust pressure formed in the exhaust port. The reaction region is formed between an upper gas distribution plate and a lower substrate.

With an increase in stack of a vertical NAND (VNAND) semiconductor wafer, a process of increasing an etching process step and performing a treatment at a cryogenic temperature was introduced in a semiconductor processing device. Since a higher etching rate and selectivity are implemented, cryogenic cooling technology is used to lower a process temperature.

A conventional cooling system for controlling a temperature of a general wafer support plate or an electrostatic chuck performs cooling through heat transfer between a cryogenic coolant and the electrostatic chuck. A coolant tube structure moving a coolant to the electrostatic chuck is used by stacking a separated upper coolant tube block and a lower coolant tube block and connecting the same with bolts.

When the aforementioned coolant tube structure is used, there may be a problem in that cumulative tolerances may occur and chamber vacuum leakage may occur due to partial contraction caused by cryogenic coolants.

### SUMMARY

The present disclosure relates to coolant tube block assemblies for fixing a stack of a coolant tube block structure with a clamp and facilitating a connection between an upper coolant tube block and a lower coolant tube block and maintenance thereof, as well as coolant tube block assemblies for easily responding to a cryogenic process by making materials of an upper coolant tube block and a lower coolant tube block differ from each other.

The present disclosure also relates to a semiconductor processing device for preventing leakage between a substrate plate and an upper coolant tube block by providing an improved connection method between the substrate plate and the upper coolant tube block.

In some implementations, a coolant tube block assembly includes: a first coolant tube block having at least one of a first coolant flow path tube and a second coolant flow path tube formed therein; a hub block configured to expose at least one of the first coolant flow path tube and the second coolant flow path tube to one side, and connected to a lower side of one end of the first coolant tube block; a second coolant tube block provided with at least one third coolant flow path tube and at least one fourth coolant flow path tube communicating with at least one of the first coolant flow path tube and the second coolant flow path tube, and stacked with the first coolant tube block through the hub block; and a clamp disposed at a lower portion of the second coolant tube block and fastened to a fastening groove formed outside the hub block so that the second coolant tube block is in close contact with the first coolant tube block.

In some implementations, a coolant tube block assembly coupled to a substrate support plate of a semiconductor processing device includes: a first coolant tube block and a second coolant tube block in which coolant flow path tubes communicating with each other are formed; a hub block coupled to one end of the first coolant tube so that the coolant flow path tube of the first coolant tube block is exposed to one side, wherein the second coolant tube block is inserted into the hub block so that the second coolant flow path tube communicates with the coolant flow path tube of the first coolant tube block; and a clamp coming into close contact with the first coolant tube block by moving the second coolant tube block vertically, and fastened to a fastening groove formed outside the hub block.

In some implementations, a semiconductor processing device includes: a wafer support plate configured to support a wafer; a first coolant tube block inserted into and fixed to a lower portion of the wafer support plate and configured to form a coolant flow path tube through which a coolant is moved to exchange heat with the wafer; a hub block coupled to one end of the first coolant tube so that the coolant flow path tube of the first coolant tube block is exposed to one side; a second coolant tube block having a coolant flow path tube inserted into the hub block and communicating with the coolant flow path tube of the first coolant tube block; and a clamp coming into close contact with the first coolant tube block by moving the second coolant tube block vertically, and fastened to a fastening groove formed outside the hub block.

In some implementations, coolant tube block assemblies are connected using a jog unit outside a vacuum chamber, thereby facilitating the connection as well as performing beneficial maintenance.

Materials having different thermal expansion coefficients for an upper coolant tube block and other components may be selected to eliminate a difference in contraction force between the blocks, thereby reducing a chamber vacuum leakage.

By supporting a lower portion of a coolant tube block assembly with an elastic member such as a spring, it is possible to reduce a difference in contraction force between an upper coolant tube block and a wafer support plate connected to which the upper coolant tube block is connected, and a cumulative tolerance caused by the accumulation of loads during the assembly process.

Furthermore, a leakage phenomenon between a substrate plate and an upper coolant tube block can be prevented by providing an improved connection method between a wafer support plate and the upper coolant tube block.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a schematic cross-sectional view of an example of a semiconductor processing device.

FIG. 2 is a schematic perspective view of an example of a substrate plate and an example of a coolant tube block assembly.

FIG. 3 is an example cross-sectional view taken along line A-A′ of FIG. 2.

FIG. 4 is an example schematic perspective view of a lower coolant tube block and a clamp.

FIG. 5 is an example schematic perspective view illustrating the clamp.

FIG. 6 is an example enlarged perspective view of a lower link member of a clamp member.

FIG. 7 is an example plan view of FIG. 6.

FIG. 8 is an example cross-sectional view illustrating a state before coupling a substrate plate and a coolant tube block assembly taken along line B-B′ of FIG. 2.

FIG. 9 is an example cross-sectional view illustrating a state in which the substrate plate of FIG. 8 and a coolant tube block assembly are coupled to each other.

FIG. 10 is an example schematic view illustrating a process in which an upper coolant tube block and a lower coolant tube block are fixed with a clamp.

FIG. 11 is a schematic view illustrating an example of an operation process of a clamp hook of FIG. 8.

### DETAILED DESCRIPTION

Hereinafter, example implementations of the present disclosure will be described with reference to the accompanying drawings.

The example implementations of the present disclosure may be changed in various different forms, and are provided for those skilled in the art to more fully explain the present disclosure. Accordingly, in the drawings, the shapes and dimensions of elements may be exaggerated for clarity, and the same reference numerals will be used throughout to designate the same or like elements.

In the present disclosure, a meaning of “being connected” is a concept including not only “directly connected” but also “indirectly connected” through another component or the like. Furthermore, in some cases, it is a concept including “electrically connected.”

In the present disclosure, expressions such as “first” and “second” are used to distinguish one component from another, and do not limit the order and/or importance of the components. In some cases, a first component may be referred to as a second component without departing from the scope of rights, or similarly, the second component may be referred to as the first component.

The terms used in the present disclosure are used only to describe an example implementation and are not intended to limit the present disclosure. In this case, singular expressions include plural expressions unless they are clearly meant differently in the context.

### Semiconductor Processing Device

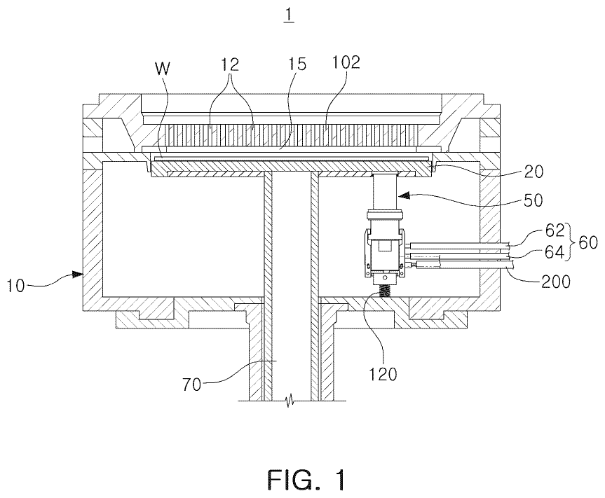

FIG. 1 is a schematic cross-sectional view of an example of a semiconductor processing device.

Referring to FIG. 1, a semiconductor processing device 1 includes a vacuum chamber 10. The vacuum chamber 10 may provide an enclosed space so that processing processes for a substrate (or a wafer W) may be performed therein. The vacuum chamber 10 may have a cylindrical shape or a rectangular cylindrical shape, but the present disclosure is not limited thereto. The vacuum chamber 10 may be formed of a metal material such as aluminum or stainless steel. The vacuum chamber 10 may perform various processes such as chemical vapor deposition (CVD), plasma-enhanced chemical vapor deposition (PECVD), reactive ion etching (RIE), annealing, oxidation, and nitridation in a vacuum state.

The semiconductor processing device 1 of the present disclosure includes a cooling system for adjusting a temperature of a wafer support plate 20.

The semiconductor processing device 1 of the present disclosure includes a wafer support plate 20, a vacuum chamber 10, and a coolant tube block assembly 50.

A semiconductor wafer W to be processed is loaded on the wafer support plate 20. The vacuum chamber 10 includes a gas distribution plate 102 in which an injection hole 12 into which a process gas is introduced is formed. The gas distribution plate 102 may be used as an upper electrode in a plasma process and may include a metal or a ceramic material. The gas distribution plate 102 may include metallic materials such as aluminum, aluminum alloys, steel, stainless steel, nickel, or nickel alloys (inconel, hastelloy, or the like) or dielectrics of ceramics such as quartz (SiO₂), SiC, SiN, Al₂O₃, AlN, and Y₂O₃. In an example implementation of the present disclosure, the gas distribution plate 102 includes aluminum having excellent corrosion resistance, reactivity, conductivity, and processability.

A plurality of injection holes 12 of the gas distribution plate 102 may be a shower head that sprays gas to a lower portion of the gas distribution plate 102. The process gas may be sprayed from a gas supply unit (not illustrated) above the gas distribution plate 102 to a reaction region 15 below the injection hole 12, through the injection hole 12. The process gas may be converted into a plasma state in the reaction region 15.

The wafer support plate 20 may be rotatably disposed in a disk shape. The wafer support plate 20 may be connected to an elevating device 70 configured to move up and down. The wafer support plate 20 may be used as a lower electrode during a plasma process, and may include a metal material or a ceramic material. The wafer support plate 20 may be a susceptor in which a heater is mounted to maintain a constant temperature of the semiconductor wafer W. The wafer support plate 20 is also referred to as an electrostatic chuck by electrostatically adsorbing and supporting the semiconductor wafer W. The wafer support plate 20 stably supports the semiconductor wafer W while performing a process for the semiconductor wafer W. The wafer support plate 20 maintains the temperature of the semiconductor wafer W while performing the process through the heater.

The wafer support plate 20 may include metallic materials such as aluminum, aluminum alloys, steel, stainless steel, nickel, or nickel alloys (inconel, hastelloy, or the like) or dielectrics of ceramics such as quartz (SiO₂), SiC, SiN, Al₂O₃, AlN, and Y₂O₃.

A flow line (not illustrated) through which a coolant flows is formed in order to maintain a certain temperature of the wafer support plate 20, and the flow line communicates with a coolant supply source (not illustrated) outside the coolant tube block assembly 50 in the vacuum chamber 10.

The coolant tube block assembly 50 is inserted into and fixed to a lower portion of the wafer support plate 20, and the coolant tube block assembly 50 is supported by an elastic member 120 at the bottom of a vacuum chamber 10.

Hereinafter, the coolant tube block assembly 50 connected to the wafer support plate 20 to supply the coolant will be described in detail.

### Coolant Tube Block Assembly

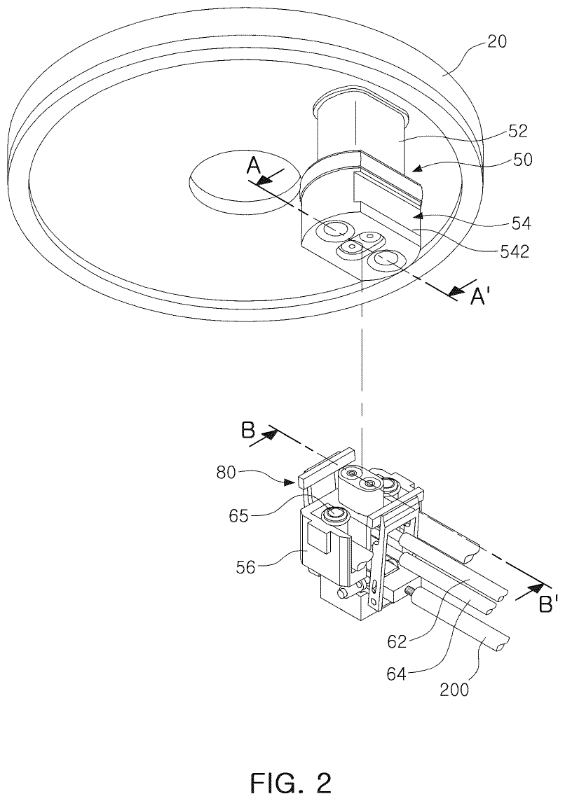

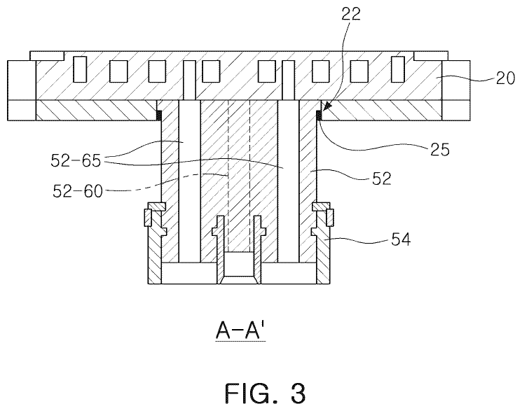

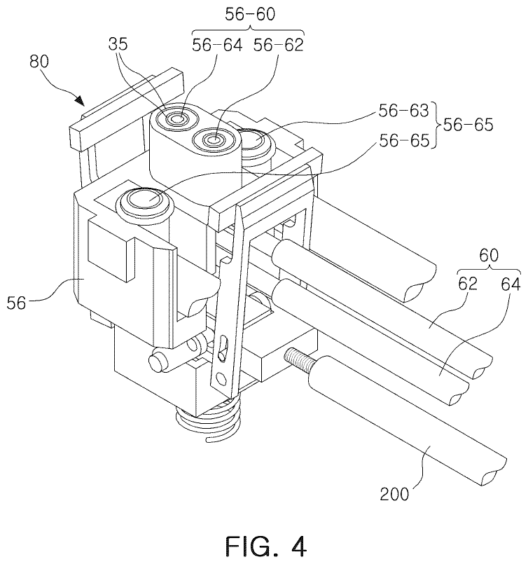

FIG. 2 is a schematic perspective view of an example of a substrate plate and an example of a coolant tube block assembly, FIG. 3 is an example cross-sectional view taken along line A-A′ of FIG. 2, and FIG. 4 is an example schematic perspective view of a lower coolant tube block and a clamp.

Referring to FIGS. 2 to 4, the coolant tube block assembly 50 of the present disclosure is a coolant supply flow path system coupled to a substrate support plate 20 of the semiconductor processing device 1 to supply a cryogenic coolant to the substrate support plate 20.

The coolant tube block assembly 50 includes a first coolant tube block 52, a hub block 54, a second coolant tube block 56, and a clamp 80.

At least one of a first coolant flow path tube 52-60 and a second coolant flow path tube 52-65 may be formed inside the first coolant tube block 52. The number of flow paths may be selected according to the type of coolant and a flow method of the coolant, and in the present implementation, each of two types of coolant has two flow paths.

Here, the first coolant flow path tube 52-60 may be a helium gas flow path tube, and the second coolant flow path tube 52-65 disposed on both sides of the first coolant flow path tube 52-60 may be a cryogenic coolant flow path tube.

The hub block 54 is an intermediate connection medium for connecting the first coolant tube block 52 and the second coolant tube block 56. The hub block 54 exposes at least one of the first coolant flow path tube 52-60 and the second coolant flow path tube 52-65 to one side, and is connected to a lower side of one end of the first coolant tube block 52.

The second coolant tube block 56 is connected to the first coolant tube block 52 through the hub block 54. The second coolant tube block 56 is equipped with at least one third coolant flow path tube 56-60 and at least one fourth coolant flow path tube 56-65 that communicate with at least one of the first coolant flow path tube 52-60 and the second coolant flow path tube 52-65 of the first coolant tube block 52. The second coolant tube block 56 is stacked with the first coolant tube block 52 through the hub block 54. The third coolant flow path tube 56-60 of the second coolant tube block 56 may be helium gas flow path tubes 56-62 and 56-64 moving in two lines, and the fourth coolant flow path tubes 56-63 and 56-65 of the second coolant tube block 56 may be a cryogenic coolant flow path tube.

The clamp 80 is disposed at a lower portion of the second coolant tube block 56 and is fastened to a fastening groove 542 formed outside the hub block 54 so that the second coolant tube block 56 is in close contact with the first coolant tube block 52.

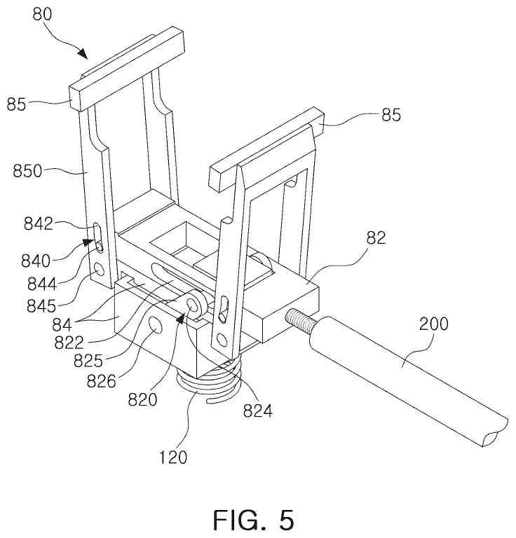

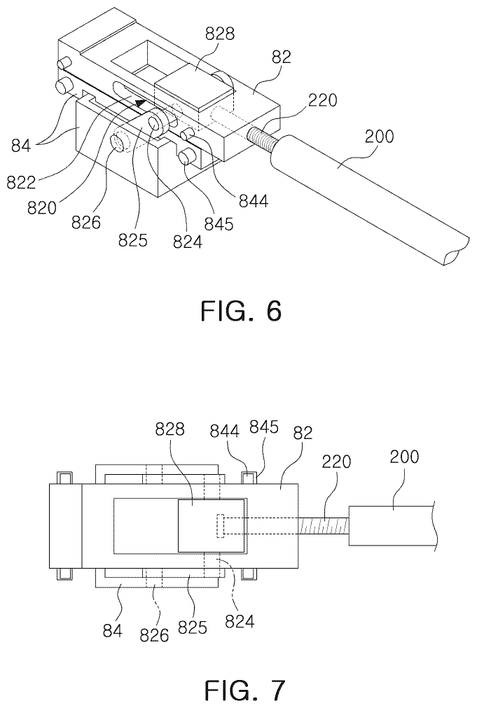

FIG. 5 is an example schematic perspective view illustrating the clamp, FIG. 6 is an example enlarged perspective view of a lower link member of a clamp member, and FIG. 7 is an example plan view of FIG. 6.

Referring to FIGS. 5 to 7, a clamp 80 adheres or detaches a second coolant tube block 56 to or from a first coolant tube block 52 through a hub block 54.

The clamp 80 of an example implementation of the present disclosure includes a first plate 82, a second plate 84, a first link portion 820, and a clamp hook 85.

The first plate 82 supports a lower portion of the second coolant tube block 56. The first plate 82 rotates a jog unit 200 exposed to the outside of a vacuum chamber 10, and a first pin 824 connected to the first plate 82 is horizontally moved by rotational force of the jog unit 200.

The second plate 84 is stacked with the first plate 82 below the first plate 82, and may be separated from the first plate 82 by a horizontal movement of the first pin 824 of the first plate 82.

A first link portion 820 connects the first plate 82 and the second plate 84, and changes the horizontal movement of the first pin 824 in the first plate 82 to a vertical movement of the second plate 84.

The clamp hook 85 is supported to be rotatable with the second plate 84, and has a second link portion 840 for changing the vertical movement of the second plate 84 to a vertical movement of the first plate 82. The second link portion 840 generates the vertical movement of the second plate 84 and the vertical movement of the first plate 82 together with the first link portion 820.

Here, when the second plate 84 moves downward, the clamp hook 85 rotates inward and is fastened to the fastening groove 542 of the hub block 54.

Conversely, when the jog unit 200 rotates in an opposite direction thereof, the clamp hook 85 rotates outward and is detached from the fastening groove 542 of the hub block 54.

The first link portion 820 includes a first pin 824, a second pin 826, and a first link member 825.

The first link portion 820 separates the first plate 82 from the second plate 84, and the first pin 824 in the first plate 82 is horizontally moved by the rotation of the jog unit 200.

The first pin 824 is guided and horizontally moved to a horizontal movement channel 822 of the first plate 82, and the second pin 826 is supported to be rotatable in a central portion of the second plate 84. Here, a horizontal moving block 828 connected to the first pin 824 horizontally moves together in the horizontal movement channel 822 of the first plate 82. The horizontal moving block 828 may be connected to a jog bolt 220 of the jog unit 200 to facilitate an operation of the jog unit 200.

The first link member 825 connects the first pin 824 and the second pin 826, and vertically moves the second plate 84 fixed to the second pin 826 through the horizontal movement of the first pin 824.

The second link portion 840 includes a guide channel 842, a third pin 844, and a fourth pin 845.

The guide channel 842 is formed in a hook frame 850 of the clamp hook 85 in a vertical direction.

The third pin 844 is vertically moved along a guide channel 842 by moving the second plate 84 in the vertical direction.

The fourth pin 845 is connected so that the hook frame 850 may rotate on both ends of the second plate 84, and rotates the hook frame 850 according to a vertical movement of the third pin 844.

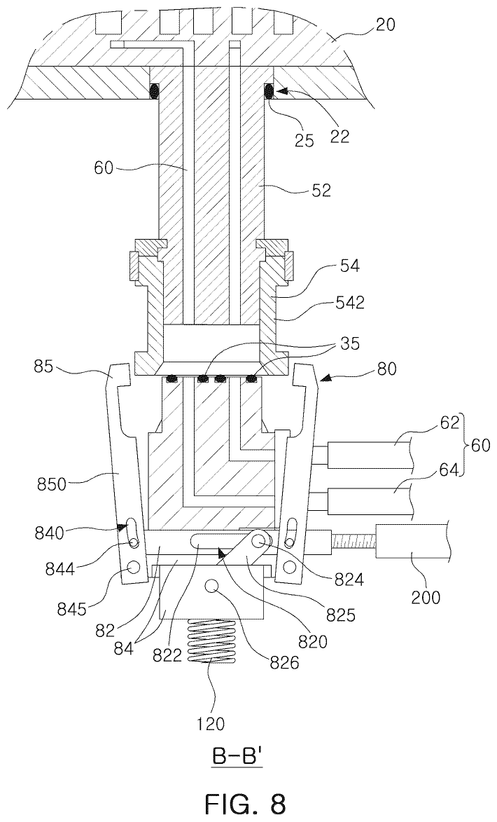

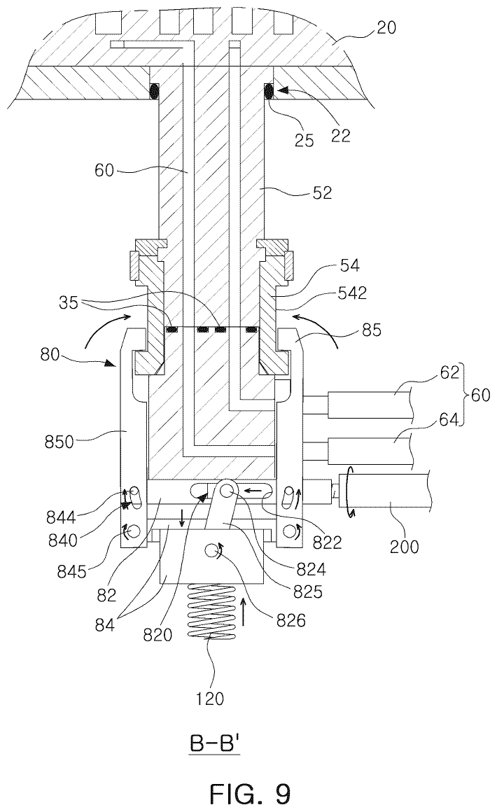

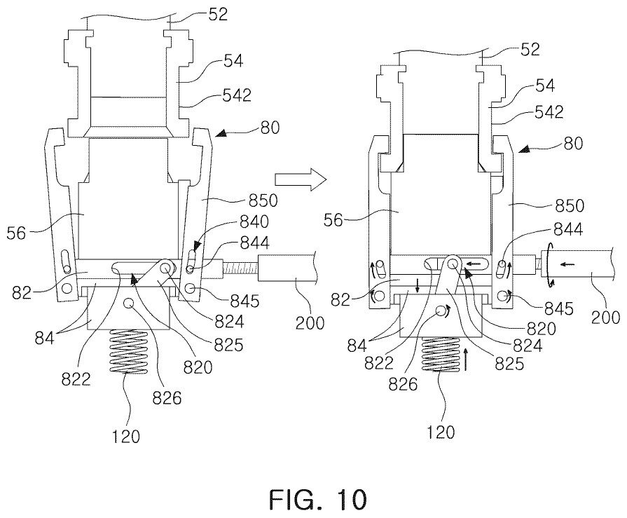

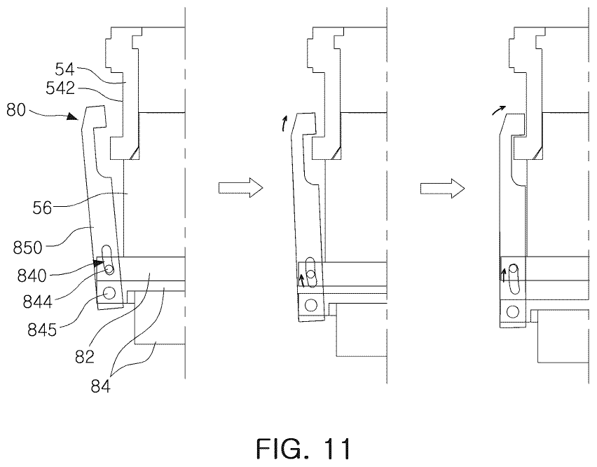

FIG. 8 is an example cross-sectional view illustrating a state before coupling a substrate plate and a coolant tube block assembly taken along line B-B′ of FIG. 2, FIG. 9 is an example cross-sectional view illustrating a state in which the substrate plate of FIG. 8 and a coolant tube block assembly are coupled to each other, FIG. 10 is an example schematic view illustrating a process in which an upper coolant tube block and a lower coolant tube block are fixed with a clamp, and FIG. 11 is a schematic view illustrating an example of an operation process of a clamp hook of FIG. 8.

Hereinafter, a coupling process of the coolant tube block assembly 50 will be described in detail with reference to FIGS. 8 to 11.

First, an upper end of a first coolant tube block 52 of a coolant tube block assembly 50 is inserted into and connected to a lower side of a wafer support plate 20. The wafer support plate 20 is provided with a coupling portion 22 into which the first coolant tube block 52 can be inserted. In the coupling portion 22 is provide with a first O-ring 25 capable of preventing leakage of a coolant.

The hub block 54 is inserted into and connected to a lower end of the first coolant tube block 52. The hub block 54 allows the first coolant block plate 52 and the second coolant block 54 to come into close contact with each other safely, and forms a fastening groove 542 to which a clamp hook 85 is fastened, on an external periphery thereof.

A contact surface between the first coolant tube block 52 and the second coolant tube block 56 is further equipped with a second O-ring 35 disposed to surround an external periphery of a coolant tube 60 to prevent leakage of the coolant.

After the second coolant tube block 56 is inserted into the hub block 54 to come into contact with the first coolant tube block 52, the clamp 80 is operated for complete close contact.

When a jog unit 200 exposed to the outside of a vacuum chamber 10 rotates, a first plate 82 of a clamp 80 connected to the jog unit 200 supports a lower portion of the second coolant tube block 56. A horizontal movement of the first plate 82 includes a horizontal movement of a first pin 824 in a horizontal movement channel 822 of the first plate 82.

The first pin 824 is guided and horizontally moved to the horizontal movement channel 822 of the first plate 82, and a first link member 825 connected to the first pin 824 pushes the second plate 84 downward. A second pin 826 supports the first link member 825 so that the first link member 825 may rotate in a central portion of the second plate 84.

An elastic member 120 supporting the clamp 80 supports the second plate 84 to provide resilience, and the first link member 825 is rotated to push the first plate 82 upward. In this case, a third pin 844 of a second link portion 840 moves upward along a guide channel 842 due to a downward movement of the second plate 84 and a standing rotation of the first link member 825. The third pin 844 is fixed to both ends of the first plate 82 and the first plate 82 also moves upward.

Here, by supporting a lower portion of the coolant tube block assembly 50 with the elastic member 120 such as a spring, it is possible to reduce a difference in contraction force between the upper coolant tube block 52 and the wafer support plate 20 connected to the upper coolant tube block 52 or a cumulative tolerance caused by accumulating loads during an assembly process.

An upper movement of the third pin 844 and the first plate 82 rotates a fourth pin 845 connected to the hook frame 850 so that the hook frame 850 is rotatable in both ends of the second plate 84, thereby rotating the hook frame 850 inward. As the hook frame 850 rotates inward, a hook 85 is fastened to and supported by the fastening groove 542 formed on an external surface of the hub block 54.

Conversely, when the jog unit 200 is rotated in an opposite direction thereof, the clamp hook 85 rotates outward and is detached from a fastening groove 542 of the hub block 54.

Coolant tube blocks 52 and 54 are connected to each other using the jog unit 200 and a clamp 80, thereby facilitating a connection operation thereof as well as performing beneficial maintenance.

On the other hand, by changing the material of the coolant tube assembly 50, it is possible to reduce a chamber vacuum leakage phenomenon by selecting a material having no difference in the contraction force between blocks even in a cryogenic process.

The first coolant tube block 52 may include a material having a lower thermal expansion coefficient than that of the clamp 80. The first coolant tube block 52 may include Al₂O₃ having a low thermal expansion coefficient, and the clamp 80, first coolant tubes 60, 62 and 64, and second coolant tubes 63 and 65 may include STS304 having a higher thermal expansion coefficient than that of Al₂O₃.

The difference in the contraction force between blocks may be eliminated by selecting materials having different thermal expansion coefficients for the upper coolant tube block and other components as described above, reducing the chamber vacuum leakage phenomenon.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

What is claimed is:

1. A coolant tube block assembly comprising:
a first coolant tube block including a first coolant flow path tube, a second coolant flow path tube, or the first coolant flow path tube and the second coolant flow path tube;
a hub block configured to expose the first coolant flow path tube, the second coolant flow path tube, or the first coolant flow path tube and the second coolant flow path tube on one side, and connected to a lower side of the first coolant tube block;
a second coolant tube block including at least one third coolant flow path tube and at least one fourth coolant flow path tube, the at least one third coolant flow path tube and the at least one fourth coolant flow path tube communicating with the first coolant flow path tube, the second coolant flow path tube, or the first coolant flow path tube and the second coolant flow path tube, the second coolant tube block stacked with the first coolant tube block through the hub block; and
a clamp disposed at a lower portion of the second coolant tube block and fastened to a fastening groove formed outside the hub block so that the second coolant tube block is in close contact with the first coolant tube block.

2. The coolant tube block assembly of claim 1, wherein the first coolant flow path tube is a helium gas flow path tube, and the second coolant flow path tube disposed on both sides of the first coolant flow path tube is a cryogenic coolant flow path tube.

3. The coolant tube block assembly of claim 1, wherein the clamp comprises:
a first plate configured to support the lower portion of the second coolant tube block;
a second plate disposed to be detachable from a lower portion of the first plate;
a first link portion configured to connect the first plate and the second plate; and
a clamp hook capable of rotating with the second plate and having a second link portion for changing a vertical movement of the second plate to a vertical movement of the first plate,
wherein the clamp hook rotates inward by a downward movement of the second plate and is fastened to the fastening groove of the hub block.

4. The coolant tube block assembly of claim 3, wherein the first link portion comprises:
a first pin moved to a horizontal movement channel of the first plate;
a second pin fixed in a central portion of the second plate and rotatable; and
a first link member configured to connect the first pin and the second pin and vertically move the second plate fixed to the second pin through a horizontal movement of the first pin.

5. The coolant tube block assembly of claim 3, wherein the second link portion comprises:
a guide channel formed in a hook frame of the clamp hook in a vertical direction;
a third pin vertically moving according to the guide channel by moving the second plate in the vertical direction; and
a fourth pin connected to the hook frame so that the hook frame rotates in both ends of the second plate and configured to rotate the hook frame according to a vertical movement of the third pin.

6. The coolant tube block assembly of claim 1, wherein an O-ring surrounding an external periphery of the first coolant flow path tube is disposed on a contact surface between the first coolant tube block and the second coolant tube block.

7. The coolant tube block assembly of claim 1, wherein the first coolant tube block includes a material having a lower thermal expansion coefficient than a material of the clamp.

8. The coolant tube block assembly of claim 7, wherein the first coolant tube block includes Al₂O₃ having a lowest thermal expansion coefficient, and the clamp, the first coolant flow path tube, and the second coolant flow path tube include STS304 having a higher thermal expansion coefficient than the Al₂O₃.

9. A coolant tube block assembly coupled to a substrate support plate of a semiconductor processing device, comprising:
a first coolant tube block and a second coolant tube block in which coolant flow path tubes communicating with each other are formed;
a hub block coupled to one end of the first coolant tube block so that a first coolant flow path tube of the first coolant tube block is exposed on one side, wherein the second coolant tube block is inserted into the hub block so that a second coolant flow path tube communicates with the coolant flow path tube of the first coolant tube block; and
a clamp coming into close contact with the first coolant tube block by moving the second coolant tube block vertically, and fastened to a fastening groove formed outside the hub block.

10. The coolant tube block assembly of claim 9, wherein the first coolant flow path tube is at least one of a helium gas flow path tube and a cryogenic coolant flow path tube.

11. The coolant tube block assembly of claim 9, wherein the clamp comprises:
a first plate configured to support a lower portion of the second coolant tube block;
a second plate detachable from a lower portion of the first plate;
a first link portion configured to connect the first plate and the second plate; and
a clamp hook fixed with the second plate, capable of rotating with the second plate, and having a second link portion for changing a vertical movement of the second plate to a vertical movement of the first plate,
wherein the clamp hook rotates inward by a downward movement of the second plate and is fastened to the fastening groove of the hub block.

12. The coolant tube block assembly of claim 11, wherein the first link portion comprises:
a first pin horizontally moved in a horizontal moving channel of the first plate;
a second pin supported in a central portion of the second plate and rotatable; and
a first link member configured to connect the first pin and the second pin and vertically move the second plate fixed to the second pin by a horizontal movement of the first pin.

13. The coolant tube block assembly of claim 11, wherein the second link portion comprises:
a guide channel formed in a hook frame of the clamp hook in a vertical direction;
a third pin vertically moving according to the guide channel by moving the second plate in the vertical direction; and
a fourth pin connected to the hook frame so that the hook frame rotates in both ends of the second plate and configured to rotate the hook frame according to a vertical movement of the third pin.

14. The coolant tube block assembly of claim 9, wherein the first coolant tube block includes a material having a lower thermal expansion coefficient than a material of the clamp.

15. The coolant tube block assembly of claim 14, wherein the first coolant tube block includes Al₂O₃ having a lowest thermal expansion coefficient, and the clamp, the first coolant flow path tube, and the second coolant flow path tube include STS304 having a higher thermal expansion coefficient than the Al₂O₃.

16. A semiconductor processing device comprising:
a wafer support plate configured to support a wafer;
a first coolant tube block inserted into and fixed to a lower portion of the wafer support plate and configured to form a coolant flow path tube through which a coolant for exchanging heat with the wafer is moved;
a hub block coupled to one end of the first coolant tube block so that the coolant flow path tube of the first coolant tube block is exposed on one side;
a second coolant tube block having a coolant flow path tube inserted into the hub block and communicating with the coolant flow path tube of the first coolant tube block; and
a clamp coming into close contact with the first coolant tube block by moving the second coolant tube block vertically, and fastened to a fastening groove formed outside the hub block.

17. The semiconductor processing device of claim 16, wherein the coolant flow path tube of the first coolant tube block is at least one of a helium gas flow path tube and a cryogenic coolant flow path tube.

18. The semiconductor processing device of claim 16, wherein the clamp comprises:
a first plate configured to support a lower portion of the second coolant tube block;
a second plate detachable from a lower portion of the first plate;
a first link portion configured to connect the first plate and the second plate and change a horizontal movement of the first plate to a vertical movement of the second plate; and
a clamp hook fixed with the second plate, capable of rotating with the second plate, and having a second link portion for changing the vertical movement of the second plate to the vertical movement of the first plate,
wherein the clamp hook rotates inward by a downward movement of the second plate and is fastened to the fastening groove of the hub block.

19. The semiconductor processing device of claim 16, further comprising at least one of:
a first O-ring disposed on a coupling portion of the wafer support plate and the first coolant tube block; and
a second O-ring disposed to surround an external periphery of the coolant flow path tube of the first coolant tube block on a contact surface between the first coolant tube block and the second coolant tube block.

20. The semiconductor processing device of claim 18, further comprising an elastic member configured to supply resilience to the second plate.
